(19) United States
(12) Patent Application Publication
(10) Pub. No.: US 2026/0343796 A1
(43) Pub. Date: Oct. 29, 2026

(54) IMMERSION COOLING SYSTEMS HAVING A CONDENSING COIL AND A FLOW-GUIDE STRUCTURE

(71) Applicant: Toyota Motor Engineering & Manufacturing North America, Inc., Plano, TX (US)

(72) Inventors: Shailesh N. Joshi, Ann Arbor, MI (US); Tianzhu Fan, Houston, TX (US); Yohei Iwahashi, South Lyon, MI (US)

(73) Assignee: Toyota Motor Engineering & Manufacturing North America, Inc., Plano, TX (US)

(21) Appl. No.: 19/193,025

(22) Filed: Apr. 29, 2025

(51) Int. Cl. H05K 7/20

(52) U.S. Cl. CPC H05K 7/20236; H05K 7/20263

(57) ABSTRACT

In one embodiment, an immersion cooling system includes a housing defining a chamber, a condensing coil disposed within the chamber and operable to receive a working fluid, where the condensing coil has a condensing surface having a first surface energy, and a flow-guide structure coupled to the condensing coil, where the flow-guide structure has a surface having a second surface energy, and the first surface energy is less than the second surface energy.

### BACKGROUND

Electronic devices, including central processing units, graphical processing units, and power modules, generate considerable amounts of heat during operation due to high processing power and energy consumption. The demand for consistent high processing power in data centers and the intensive computational requirements of cryptocurrency mining exacerbate the thermal loads.

Effective cooling is important to maintain performance and prevent overheating and damage to the electronic devices. Various cooling techniques may be employed to cool electronic devices, such as the use of heat sinks, air cooling, liquid cooling. Liquid cooling techniques may include immersion cooling, where the electronic devices are directly submerged in a dielectric cooling fluid. In two-phase immersion cooling, the electronic devices are cooled by the phase change of liquid to vapor of the dielectric cooling liquid. Vapor rises up where it is then condensed and then drips back down toward the electronic devices in a closed system. However, there are disadvantages to the two-phase immersion cooling system, such as increased flow resistance due to the intermingling of the flow paths for both the vapor and the condensed liquid.

### BRIEF SUMMARY

In one embodiment, an immersion cooling system includes a housing defining a chamber, a condensing coil disposed within the chamber and operable to receive a working fluid, where the condensing coil has a condensing surface having a first surface energy, and a flow-guide structure coupled to the condensing coil, where the flow-guide structure has a surface having a second surface energy, and the first surface energy is less than the second surface energy.

In another embodiment, an immersion cooling system includes a housing defining a chamber, a cooling fluid within the chamber, a condensing coil disposed within the chamber and operable to receive a working fluid, where the condensing coil has a condensing surface having a first surface energy, a flow-guide structure coupled to the condensing coil, where the flow-guide structure has a surface having a second surface energy, and the first surface energy is less than the second surface energy, and one or more heat generating components disposed within the cooling fluid.

### BRIEF DESCRIPTION OF THE SEVERAL VIEWS OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 illustrates an example immersion cooling system according to one or more embodiments described and illustrated herein.

FIG. 2 illustrates droplets having various contact angles due to surface energy of surfaces according to one or more embodiments described and illustrated herein.

FIG. 3 illustrates an example surface of a condensing coil or flow-guide structure according to one or more embodiments described and illustrated herein.

FIG. 4 illustrates another embodiment of a flow-guide structure according to one or more embodiments described and illustrated herein.

FIG. 5 illustrates an example data center, crypto mining rig, and super computer including immersion cooling systems according to one or more embodiment described and illustrated herein.

### DETAILED DESCRIPTION

Embodiments of the present disclosure are directed to immersion cooling systems having improved cooling efficiency by the use of a condensing coil and a flow-guide structure with different surface energies to both encourage the condensing of vapor and the flow of condensed liquid back to a cooling fluid reservoir.

Immersion cooling is a thermal management technique where electronic components or other heat generating components are submerged in a thermally conductive dielectric liquid. This method efficiently dissipates heat by directly transferring it from the components to the liquid, bypassing the need for traditional air cooling systems. Immersion cooling is increasingly popular in high-performance computing, data centers, and some niche applications like crypto mining. The immersion cooling has the benefits of high efficiency, reduced energy use, noise reduction, component longevity, and scalability.

There are two types of immersion cooling: single phase and two-phase. In single phase immersion cooling, the dielectric cooling liquid absorbs heat and circulates through a heat exchanger without changing state. In two-phase immersion cooling, the dielectric cooling liquid boils upon absorbing heat, transitioning to vapor. The vapor is then condensed back to liquid by a cooling coil or a condenser. Then, the condensed cooling liquid naturally drips or flows back into the bulk liquid reservoir due to gravity. This is a passive process that requires the condenser to be positioned above the liquid level.

One of the issues encountered in conventional two-phase immersion cooling system is that the vapor and liquid flow paths are intermixed, which creates flow resistance for the condensed liquid back into the reservoir in which the heat generating components are submerged. The increased flow resistance lowers the cooling efficiency of the immersion cooler.

Embodiments of the present disclosure provide immersion cooling systems with separate dedicated vapor flow paths and condensed liquid flow paths by the use of a condensing coil and flow-guide structure having different surface energies.

Various embodiments of immersion cooling systems including a condensing coil and flow-guide structure having different surface energies.

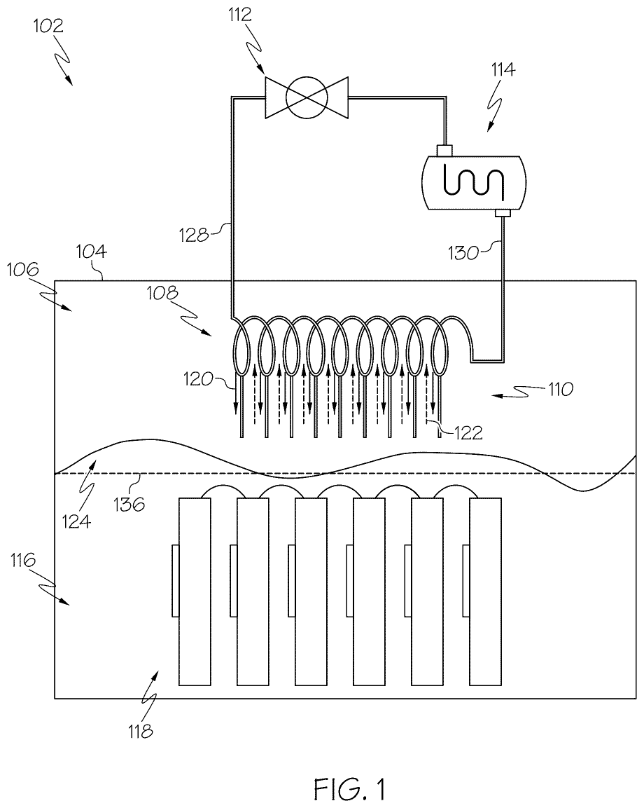

Referring now to FIG. 1, an example immersion cooling system 102 is schematically illustrated. The illustrated immersion cooling system 102 generally comprises a housing 104 that defines a chamber 106, a condensing coil 108, and a flow-guide structure 110. The immersion cooling system 102 also includes a pump 112 and a heat exchanger 114 for continuously cycling a working fluid into the condensing coil 108. The condensing coil 108 includes an inlet 128 for receiving the 132, such as from the pump 112, and an outlet 130 that removes the warned working fluid from the condensing coil 108 and provides it to a heat exchanger 114. The heat exchanger 114 is operable to receive the warmed working fluid and reduce its temperature so it may be returned to the condensing coil 108. The pump 112 moves the working fluid through the condensing coil 108 and the heat exchanger 114 in a closed loop system. It should be understood that additional components may be utilized, such as a reservoir that stores the working fluid. Additionally, some immersion cooling systems may not include the heat exchanger 114 and/or the pump 112.

The working fluid may be water or other fluids, such as R-32, R-134 and other refrigerants.

The chamber 106 defined by the housing 104 is partially filled with a cooling fluid 116 leaving a gap between the liquid surface 124 and an upper portion of the housing 104. One or more heat generating components 118 are immersed within the cooling fluid 116. The cooling fluid 116 may be any two-phase dielectric fluid capable of receiving electronic components without causing electrical shorts to the electronic components. Non-limiting dielectric fluids include synthetic oils, esters and fluorochemicals.

The one or more heat generating components 118 may be any component that generates heat flux that is to be removed. Non-limiting example heat generating components include central processing units, graphical processing units, power switching devices, voltage regulators, crypto-mining components, and data switch devices. As shown in FIG. 1, an array of heat generating components 118 may be immersed in the cooling fluid 116 within the chamber 106. Contact with the cooling fluid 116 causes heat to transfer from the one or more heat generating components 118 to the cooling fluid 116, which causes the cooling fluid 116 within the reservoir to change from the liquid phase to the gas phase as vapor 122. The vapor 122 rises from the liquid surface 124 in a direction toward the condensing coil 108.

The condensing coil 108 is at least partially disposed within the chamber 106 and as a coiled shape. As stated above, the condensing coil 108 is operable to receive a working fluid that lowers the temperature of the condensing coil 108 relative to the chamber 106 and the vapor 122. The condensing coil 108 may be fabricated from any thermally conductive material, such as metal, metal alloys and thermally conductive composite materials.

The surface of the condensing coil 108 has a first surface energy that encourages condensation. More particularly, the surface of the condensing coil 108 has a first surface energy such that the surface of the condensing coil 108 is lyophobic or super-lyophobic. As used herein, the terms lyophobic and super-lyophobic also mean hydrophobic and super-hydrophobic, respectively. A lyophobic surface defines a surface at which the liquid contact angle θ is greater than 90 degrees, and a super-lyophobic surface defines a surface at which the liquid contact angle θ is greater than 150 degrees. A lyophilic surface defines a surface at which the liquid contact angle θ is smaller than 90 degrees, and a super-lyophilic surface defines a surface at which the liquid contact angle θ is nearly 0 degrees (i.e., the liquid spreads out completely). As used herein, the terms lyophilic and super-lyophilic also mean lyophilic and super-lyophilic, respectively.

The liquid contact angle is the angle formed at the junction where a droplet meets a solid surface. It is measured between the solid surface and the tangent to the droplet at the contact point.

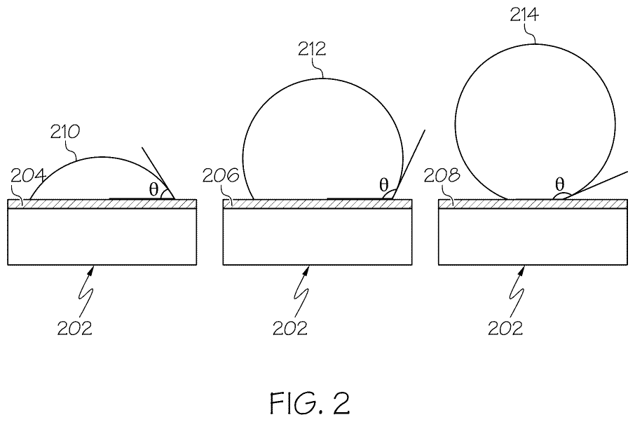

Referring to FIG. 2, the droplet 210 on surface 204 of a structure 202 has a contact angle θ less than 90 degrees. Thus, surface 204 is lyophilic. Droplet 212 on surface 206 of the structure 202 has a contact angle θ greater than 90 degrees. Thus, surface 206 is lyophobic. Droplet 214 on surface 208 has a contact angle θ greater than 150 degrees. Thus, surface 208 is super-lyophobic.

The surface of the condensing coil 108 is treated so that it is lyophobic or super-lyophobic. As non-limiting examples, the surface of the condensing coil 108 may be made lyophobic or super-lyophobic by surface texturing and/or by application of a low surface coating, such as, without limitation, silicone, polypropylene, polyethylene, and polytetrafluoroethylene. The lyophobic or super-lyophobic surface of the condensing coil 108 encourages water droplets to form on the cold condensing coil 108 that spread across the surface, and also to roll off the surface of the condensing coil 108.

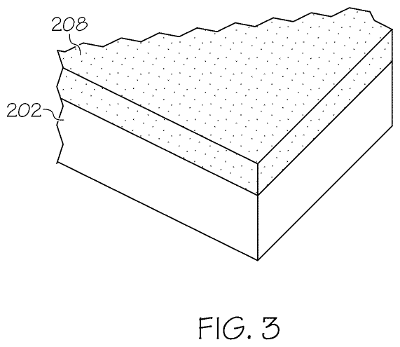

Referring to FIG. 3, an example surface 208 provided on a structure 202, such as a condensing coil 108, is illustrated in greater detail. The surface 208 is either textured or is a coating or layer that provides a low surface energy (e.g., less than 36 dynes/cm) providing a lyophobic or super-lyophobic surface for droplets with large contact angles θ can form.

Referring once again to FIG. 1, the heat generating components 118 create heat that warms the cooling fluid 116 such that it boils and changes phase from a liquid to vapor 122. The vapor 122 rises in a direction away from the liquid surface 124 and toward the condensing coil 108. The condensing coil 108 receives the vapor 122 created by the one or more heat generating components and, because the condensing coil 108 is cooled by the working fluid, the condensing coil 108 condenses the vapor 122 into a condensed liquid 120. The lyophobic or super-lyophobic surface of the condensing coil 108 encourages droplets to form across the surface and roll off.

The flow-guide structure 110 is attached to the condensing coil 108 such that the two components are fluidly coupled to one another. For example, the flow-guide structure 110 may be soldered to the condensing coil 108 or adhered by an adhesive. The flow-guide structure 110 is fabricated from a thermally conductive material, such as metal, metal alloys, and thermally conductive composite materials. In other embodiments, the flow-guide structure 110 is not fabricated from a thermally conductive material, and may be fabricated from other materials, such as plastic.

The flow-guide structure 110 has a surface with a second surface energy that is greater than the first surface energy of the condensing coil 108. The second surface energy of the surface of the flow-guide structure 110 is such that the surface is lyophilic or super-lyophilic. The flow-guide structure 110 may be made lyophilic or super-lyophilic by chemical coating, chemical modification, ultra-violet treatment, plasma treatment, and physical structuring, as non-limiting examples.

The end of the flow-guide structure 110 is separated from the liquid surface 124 so that wicking of the cooling fluid 116 within the reservoir into the flow-guide structure 110 is prevented.

Being lyophilic or super-lyophilic, the surface of the flow-guide structure 110 encourages the droplets of the condensed liquid 120 to be pulled away from the surface of the surface 208. The condensed liquid 120 spreads out along the flow-guide structure 110 due to the high surface energy. Gravity causes the condensed liquid 120 to flow along the flow-guide structure 110 and drop into the reservoir of the chamber 106 to once again cool the one or more heat generating components 118.

In the embodiment of FIG. 1, the flow-guide structure 110 is configured as an array of fins having a lyophilic or super-lyophilic surface. As a non-limiting example, the fins may be pin fins. The flow-guide structure 110 separates the vapor 122 flow path and the condensed liquid 120 flow path, thereby reducing resistance and improving cooling performance of the immersion cooling system 102.

Heat created by the heat generating components 118 is transferred to the cooling fluid 116, which turns the cooling fluid 116 into a vapor 122 and therefore cools the heat generating components 118 by two-phase cooling. The vapor 122 moves toward the condensing coil 108. The cold working fluid 132 circulating within the condensing coil 108 receives heat from the vapor 122, causing the vapor 122 to condense on the condensing coil 108 as condensed liquid 120. The condensed liquid 120 forms into droplets that roll off of the lyophobic or super-lyophobic surface of the condensing coil 108. The condensed liquid 120 flows into the lyophilic or super-lyophilic flow-guide structure 110, which draws the condensed liquid 120 down away from the condensing coil 108. The condensed liquid 120 then drips down from the flow-guide structure 110 back into to the cooling fluid 116 reservoir within the chamber. The warmed working fluid leaves the condensing coil 108 through the outlet 130 where it is chilled by the heat exchanger 114 and then reintroduced into the condensing coil 108 by the pump 112.

In some embodiments, a protective membrane 136 is provided between the flow-guide structure 110 and the array of heat generating components 118. The protective membrane 136 may be included to prevent the condensing coil 108 and the flow-guide structure 110 from falling down and touching the heat generating components 118, which may cause short-circuiting or other issues. The protective membrane 136 may include any material capable of allowing the condensed liquid 120 and vapor 122 to pass through but prevent the condensing coil 108 and the flow-guide structure 110 from reaching the heat generating components 118.

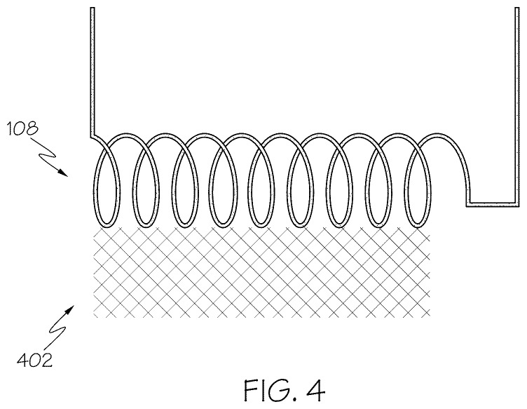

Embodiments are not limited to a flow-guide structure 110 having an array of fins. Referring now to FIG. 4, a flow-guide structure 402 configured as a lattice or a mesh is illustrated. The flow-guide structure 402 has a lyophilic or super-lyophilic surface as described with respect to the flow-guide structure 110 shown in FIG. 1. Condensed liquid 120 that forms on the lyophobic or super-lyophobic condensing coil 108 rolls off the condensing coil 108 and is wicked into the flow-guide structure 402, where it then drops down into the cooling fluid 116 within the reservoir.

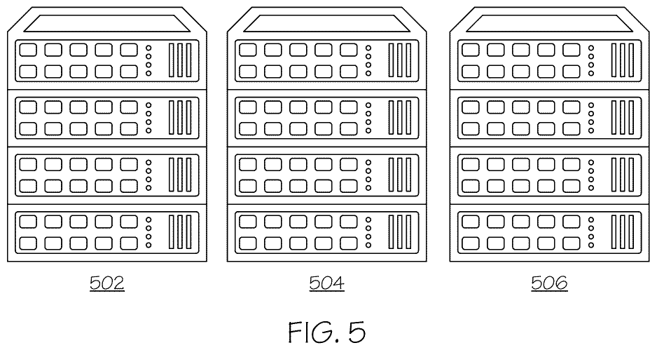

FIG. 5 illustrates example applications for the immersion cooling systems described herein. The immersion cooling systems may be used in data center 502, crypto mining rigs 504, and supercomputers 506 as non-limiting examples. However, it should be understood that the immersion cooling system described herein may be employed in any application where heat is to be removed from heat generating components.

It should now be understood that embodiments of the present disclosure are directed to immersion cooling systems for cooling heat generating components, such as electronic components, using a lyophobic or super-lyophobic condensing coil and a lyophilic or super-lyophilic flow-guide structure. The condensing coil is cooled by a circulating working fluid. The condensing coil condenses vapor from a dielectric cooling fluid heated by the heat generating components. The condensed liquid forms into droplets due to the lyophobic or super-lyophobic surface of the condensing coil. The droplets roll off of the condensing coil and into the flow-guide structure. The lyophilic or super-lyophilic flow-guide structure wicks the condensed liquid away from the condensing coil and moves to toward a reservoir of cooling fluid within the chamber of the immersion cooling system. Embodiments enhance the transport rate of the condensed liquid by use of the flow-guide structure. Further, separation of the liquid and vapor flow paths provided by the flow-guide structure allows efficient supply of liquid to the pool of cooling liquid within the chamber.

It is noted that the terms “substantially” and “about” and “approximately” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. An immersion cooling system comprising:
a housing defining a chamber;
a condensing coil disposed within the chamber and operable to receive a working fluid, wherein the condensing coil has a condensing surface having a first surface energy; and
a flow-guide structure coupled to the condensing coil, wherein the flow-guide structure has a surface having a second surface energy, and the first surface energy is less than the second surface energy.

2. The immersion cooling system of claim 1, wherein the flow-guide structure comprises a plurality of fins.

3. The immersion cooling system of claim 2, wherein the plurality of fins comprises a plurality of pin fins.

4. The immersion cooling system of claim 1, wherein the flow-guide structure comprises a lattice.

5. The immersion cooling system of claim 1, wherein the immersion cooling system has separated vapor flow paths and condensed liquid flow paths.

6. The immersion cooling system of claim 1, wherein the condensing surface of the condensing coil is lyophilic or hydrophilic and the surface of the flow-guide structure is lyophobic or hydrophobic.

7. The immersion cooling system of claim 1, further comprising a cooling fluid within the chamber.

8. The immersion cooling system of claim 1, wherein the condensing surface comprises one of a coating, a chemical modification and surface texturing.

9. The immersion cooling system of claim 1, further comprising:
a pump; and
a heat exchanger, wherein the pump and the heat exchanger are fluidly coupled to the condensing coil.

10. An immersion cooling system comprising:
a housing defining a chamber;
a cooling fluid within the chamber;
a condensing coil disposed within the chamber and operable to receive a working fluid, wherein the condensing coil has a condensing surface having a first surface energy;
a flow-guide structure coupled to the condensing coil, wherein the flow-guide structure has a surface having a second surface energy, and the first surface energy is less than the second surface energy; and
one or more heat generating components disposed within the cooling fluid.

11. The immersion cooling system of claim 10, wherein the flow-guide structure comprises a plurality of fins.

12. The immersion cooling system of claim 11, wherein the plurality of fins comprises a plurality of pin fins.

13. The immersion cooling system of claim 10, wherein the flow-guide structure comprises a lattice.

14. The immersion cooling system of claim 10, wherein the immersion cooling system has separated vapor flow paths and condensed liquid flow paths.

15. The immersion cooling system of claim 10, wherein the condensing surface of the condensing coil is lyophilic or hydrophilic and the surface of the flow-guide structure is lyophobic or hydrophobic.

16. The immersion cooling system of claim 15, wherein the one or more heat generating components comprises one or more electronic components.

17. The immersion cooling system of claim 16, wherein the one or more electronic components comprises an array of electronic components.

18. The immersion cooling system of claim 10, further comprising a protective membrane separating a surface of the cooling fluid from the flow-guide structure.

19. The immersion cooling system of claim 10, further comprising:
a pump; and
a heat exchanger, wherein the pump and the heat exchanger are fluidly coupled to the condensing coil.

20. The immersion cooling system of claim 10, wherein the condensing surface comprises one of a coating, a chemical modification and surface texturing.
